(19) United States
(12) Patent Application Publication
(10) Pub. No.: US 2011/0286819 A1
(43) Pub. Date: Nov. 24, 2011

(54) SUBSTRATE PROCESSING APPARATUS AND SUBSTRATE PROCESSING METHOD

(75) Inventors: Koji SHIBATA, Toyama (JP); Tomoshi TANIYAMA, Toyama (JP); Takayuki NAKADA, Toyama (JP)

(73) Assignee: HITACHI KOKUSAI ELECTRIC INC., Tokyo (JP)

(21) Appl. No.: 13/109,566

(22) Filed: May 17, 2011

(30) Foreign Application Priority Data
May 20, 2010 (JP) 2010-116103
Mar. 4, 2011 (JP) 2011-047473

(51) Int. Cl. H01L 21/677; B25J 9/00

(52) U.S. Cl. 414/222.02; 414/222.01

(57) ABSTRACT

A substrate processing apparatus includes a reactor; at least two boat conveying devices configured to convey at least two boats; at least one boat support table configured to support the at least two boats, the boat support table being movable to a position below the reactor; and a control unit configured to control the boat conveying devices such that when a first boat of the at least two boats supported by a first boat conveying device of the plurality of boat conveying devices holds a processed substrate processed by the reactor and is moved back to a position spaced apart from the reactor, a second boat of the at least two boats holding an unprocessed substrate is loaded into the reactor using a second boat conveying device of the at least two boat conveying devices.

### CROSS-REFERENCE TO RELATED APPLICATIONS

This application is based upon and claims the benefit of priority from Japanese Patent Application No. 2011-047473, filed on Mar. 4, 2011, and Japanese Patent Application No. 2010-116103, filed on May 20, 2010, the entire contents of which are incorporated herein by reference.

### TECHNICAL FIELD

Embodiments described herein relate to a substrate processing apparatus and method for processing substrates such as semiconductor substrates or glass substrates.

### BACKGROUND

In a substrate processing apparatus, e.g., a vertical CVD diffusion apparatus, for processing substrates with a vertical reactor, a boat holding a plurality of substrates is loaded into the reactor through the use of a boat elevator, so that the substrates are processed in the reactor.

When using a substrate processing apparatus for processing substrates held by a boat, a two-boat type substrate processing apparatus can be used to improve throughput. This substrate processing apparatus is provided with two boats and is capable of efficiently processing substrates. In this apparatus, while one set of substrates held by one of the boats are being processed, the other set of substrates stored in a substrate storage cassette are transferred to the other boat. Also, when the one set of substrates are completely processed, the two boats are interchanged with each other to process the other set of substrates (see JP2003-31643A).

In a one type of substrate processing apparatus, wafers of 300 mm in diameter are processed. In order to further improve throughput, it is required to use large-diameter wafers, e.g., 450 mm-diameter wafers. However, this results in an increase in the relative size of a carrier device of the substrate processing apparatus, an enlarged footprint and an increase in the substitution time and use amount of N₂ within a transfer chamber, thereby affecting productivity.

### SUMMARY

The present disclosure provides some embodiments of a substrate processing apparatus and method that may satisfy two conflicting requirements, i.e., a throughput increase and a footprint reduction.

According to one embodiment, there is provided a substrate processing apparatus, including a reactor; at least two boat conveying devices configured to convey at least two boats; at least one boat support table configured to support the at least two boats, the boat support table being movable to a position below the reactor; and a control unit configured to control the boat conveying devices such that when a first boat of the at least two boats supported by a first boat conveying device of the plurality of boat conveying devices holds a processed substrate processed by the reactor and is moved back to a position spaced apart from the reactor, a second boat of the at least two boats holding an unprocessed substrate is loaded into the reactor using a second boat conveying device of the at least two boat conveying devices.

The control unit may control the movement of the boat support table to the position below the reactor, and control the boat conveying devices to convey the first boat to the boat support table using the first boat conveying device, to discharge the processed substrate held in the first boat, to charge the unprocessed substrate to be subsequently processed into the first boat and to cause the first boat to wait in the position spaced apart from the reactor using the second boat conveying device.

According to another embodiment, there is provided a substrate processing method, including: holding a processed substrate processed by a reactor in a first boat; supporting the first boat with a first boat conveying device; moving the first boat conveying device to a position spaced apart from the reactor; moving a second boat into the reactor using a second boat conveying device, the second boat holding an unprocessed substrate.

The method may further include moving at least one boat support table to a position below the reactor, conveying the first boat to the boat support table using the first boat conveying device, discharging the processed substrate held in the first boat, charging the unprocessed substrate to be subsequently processed into the first boat and causing the first boat to wait in the position spaced apart from the reactor using the second boat conveying device. According to still another embodiment, there is provided a substrate processing apparatus, including: at least two reactors; at least two boat conveying devices configured to convey at least two boats; at least one boat support table configured to support the at least two boats, the at least one boat support table being movable from a position below a first reactor of the at least two reactors to a position below a second reactor of the at least two reactors; and a control unit configured to control the boat conveying devices such that, when a first boat of the at least two boats supported by a first boat conveying device of the at least two boat conveying devices holds a processed substrate processed by the first reactor and the first boat conveying device is moved back to a position spaced apart from the reactors, a second boat of the at least two boats holding an unprocessed substrate is moved into the first reactor using a second boat conveying device of the at least two boat conveying devices, the at least one boat support table is moved from the position below the first reactor to the position below the second reactor, the first boat is conveyed to the at least one boat support table using the first boat conveying device, the processed substrate held in the first boat is discharged, the unprocessed substrate to be subsequently processed is charged and moved to the first boat, and the first boat is caused to wait in the position spaced apart from the reactors.

With the above embodiments, it is possible to meet two conflicting requirements, i.e., a throughput increase and a footprint reduction.

### BRIEF DESCRIPTION OF THE DRAWINGS

FIG. 1 is a schematic perspective view showing a substrate processing apparatus according to a first embodiment.

FIG. 2 is a plan view of major parts of the substrate processing apparatus of the first embodiment.

FIG. 3 is a schematic perspective view showing a SCARA arm used in the first embodiment.

FIGS. 4A and 4B are top views of the SCARA arm used in the first embodiment.

FIGS. 5A through 5I are views for explaining how to transfer boats used in the first embodiment.

FIG. 6 is a view showing the configuration of a controller used in the first embodiment.

FIG. 7 is a flowchart showing the actions of the controller used in the first embodiment.

FIG. 8 is a schematic perspective view showing a substrate processing apparatus according to a second embodiment.

FIGS. 9A through 9D illustrate a boat transfer flow in the substrate processing apparatus of the second embodiment, the lower part in each view being a side elevation of reactors, SCARA arms and their vicinities, and the upper part in each view being a cross section taken along line D-D.

FIGS. 9E through 9H are a continuation of the boat transfer flow in the substrate processing apparatus of the second embodiment illustrated in FIGS. 9A to 9D, the lower part in each view being a side elevation of reactors, SCARA arms and their vicinities, and the upper part in each view being a cross section taken along line D-D.

FIGS. 9I through 9L are a continuation of the boat transfer flow in the substrate processing apparatus of the second embodiment illustrated in FIGS. 9E to 9H, the lower part in each view being a side elevation of reactors, SCARA arms and their vicinities, and the upper part in each view being a cross section taken along line D-D.

FIGS. 9M through 9P are a continuation of the boat transfer flow in the substrate processing apparatus of the second embodiment illustrated in FIGS. 9I to 9L, the lower part in each view being a side elevation of reactors, SCARA arms and their vicinities, and the upper part in each view being a cross section taken along line D-D.

FIG. 9Q is a continuation of the boat transfer flow in the substrate processing apparatus of the second embodiment illustrated in FIGS. 9M to 9P, the lower part in this view being a side elevation of reactors, SCARA arms and their vicinities, and the upper part in this view being a cross section taken along line D-D.

FIG. 10 is a schematic perspective view showing a substrate processing apparatus according to a comparative example.

FIG. 11 is a plan view of major parts of the substrate processing apparatus of the comparative example.

FIGS. 12A through 12G are views for explaining how to transfer boats used in the comparative example.

### DETAILED DESCRIPTION

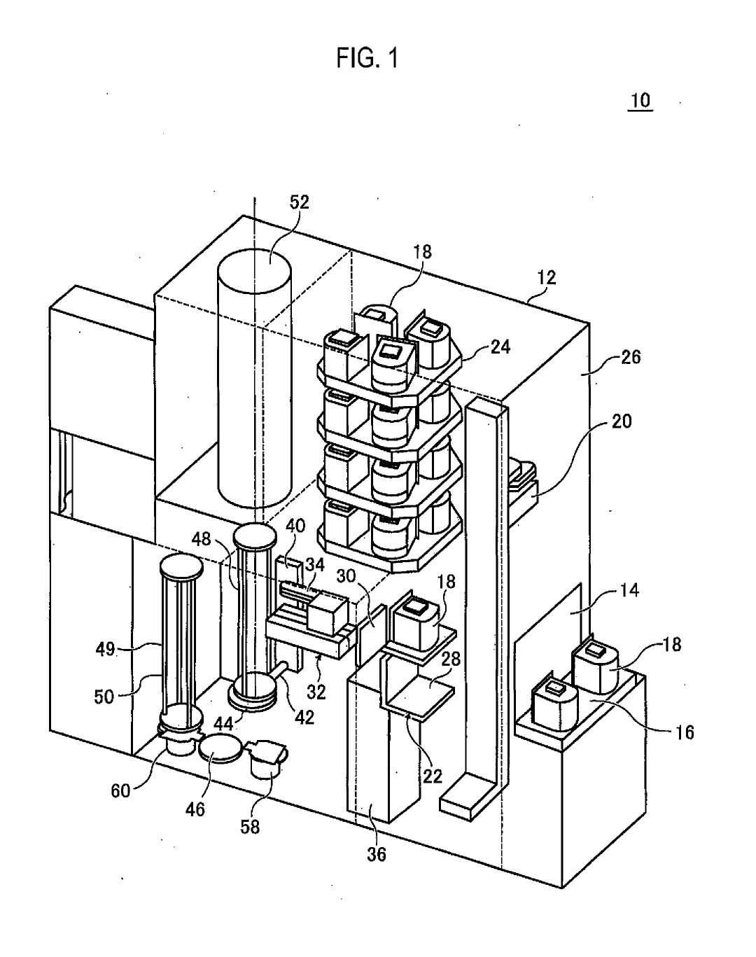

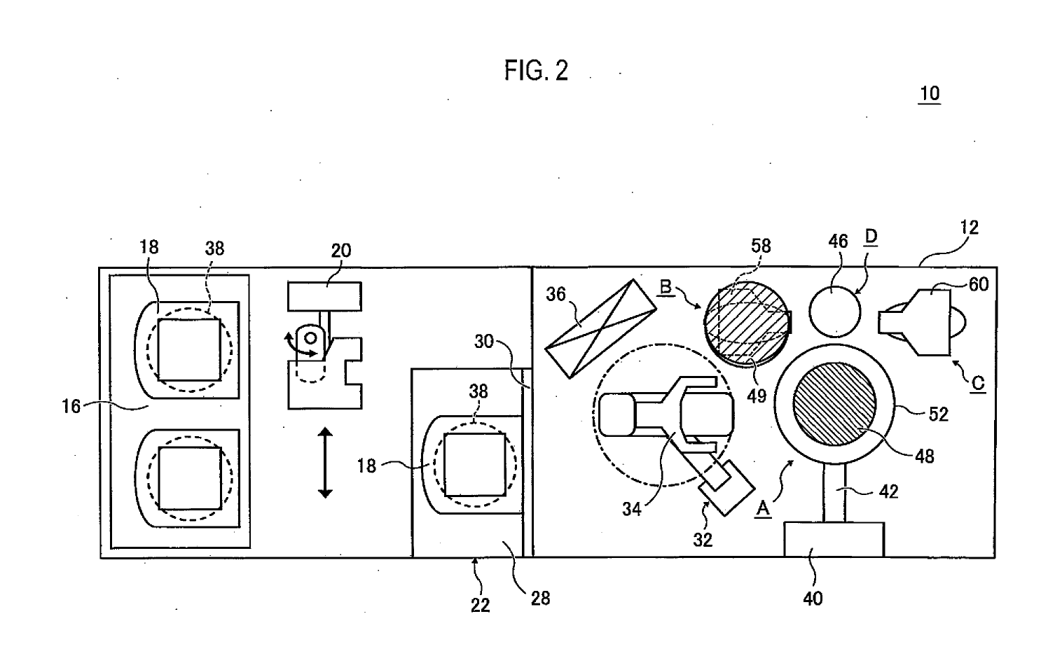

Certain embodiments will now be described in detail with reference to the accompanying drawings. FIG. 1 is a perspective view of a two-boat-interchangeable substrate processing apparatus according to a first embodiment. FIG. 2 is a plan view of the two-boat-interchangeable substrate processing apparatus.

The substrate processing apparatus 10 of the first embodiment includes a housing 12 having a gate 14 defined on the front surface thereof. A cassette delivery stage 16 is provided outside and below the gate 14. Two substrate storage cassettes 18 may be placed on the cassette delivery stage 16. The substrate storage cassettes 18 may be plastic-made sealable containers. For example, twenty five substrates are loaded into the substrate storage cassettes 18 in multiple layers.

A cassette loader 20 is installed opposite to the gate 14. The cassette loader 20 is movable in any horizontal direction (e.g., back and forth or lateral directions) and vertical direction. The cassette loader 20 is capable of conveying the substrate storage cassettes 18 to a cassette opener 22 or a cassette rack 24, both of which will be described later.

The cassette opener 22 is provided at the opposite side of the cassette loader 20 from the gate 14. The cassette opener 22 is located off-center toward one lateral surface 26 of the housing 12.

The cassette opener 22 includes a lifting table 28 on which the substrate storage cassettes 18 may be placed one above the other and a door opening/closing mechanism 30 configured to open a door (not shown) of the substrate storage cassettes 18 placed on the lifting table 28.

The cassette rack 24 is of a rotary type and is provided above the cassette opener 22. The substrate storage cassettes 18 are conveyed to the cassette rack 24 by means of the cassette loader 20.

A substrate transfer machine 32 is installed at the opposite side of the cassette opener 22 from the cassette loader 20. The substrate transfer machine 32 includes a pair of tweezers 34 configured to be movable backward/forward or rotatable. The substrate transfer machine 32 may be moved upward and downward by a transfer machine elevator (not shown).

A notch alignment device 36 is provided between the cassette opener 22 and the substrate transfer machine 32. The notch alignment device 36 is used in aligning the substrates 38 held within the substrate storage cassettes 18.

A boat elevator 40 is provided at the rear surface side of the substrate transfer machine 32. The boat elevator 40 includes a lifting arm 42 configured to be moved upward and downward by a lifting motor (not shown in the drawings).

A reactor mouth cap 44 is provided in the tip end portion of the lifting arm 42. A boat table (not shown) of predetermined height may be placed on the upper surface of the reactor mouth cap 44, thereby providing a boat transfer position. Substrate holders (boats) 48 and 49 configured to horizontally hold processing-target substrates (e.g., wafers) 38 in multiple layers are placed on the boat table. The boats 48 and 49 are made of, e.g., glass which is composed of quartz, silicon carbide, silicon and other substances. Each of the boats 48 and 49 includes three columns 50, e.g., made of quartz. 100 to 150 substrates 38 may be loaded to the slot defined by the columns 50.

A reactor 52 including a reaction chamber and a heater is provided above the reactor mouth cap 44. The reactor 52 has a reactor mouth (not shown) defined in the lower portion thereof. The position right below the reactor mouth becomes a boat loading/unloading position A and also a substrate loading/unloading position where the substrates 38 are loaded into or unloaded from the boats 48 and 49. The first boat 48 and the second boat 49 are alternately loaded into and unloaded from the reactor mouth. The reactor mouth cap 44 is fitted to the reactor mouth to seal the reactor 52 to be air-tight. The reactor 52 includes a heater (not shown in the drawings). The substrates 38 are processed by the reactor 52 under the presence of a reaction gas.

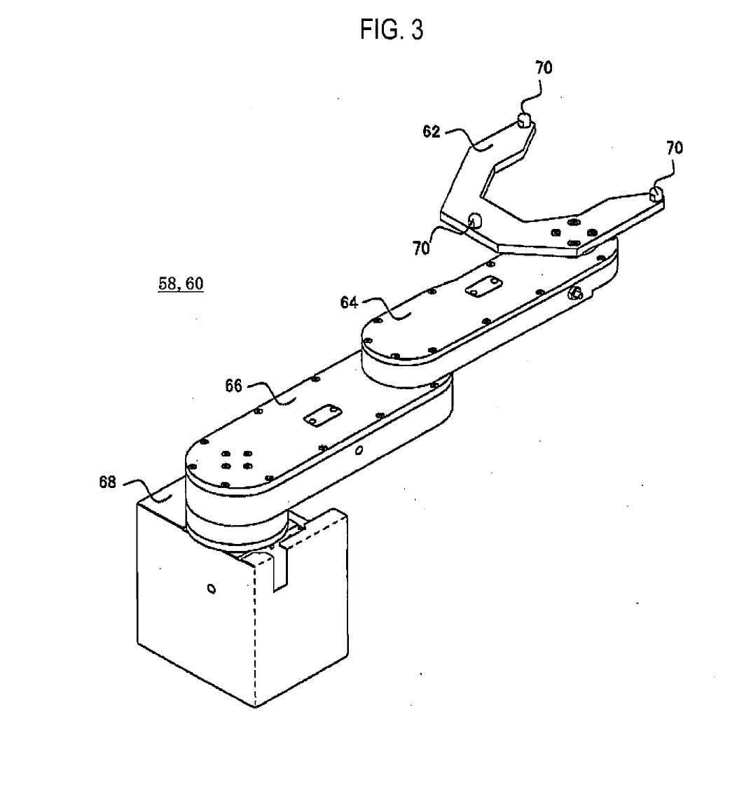

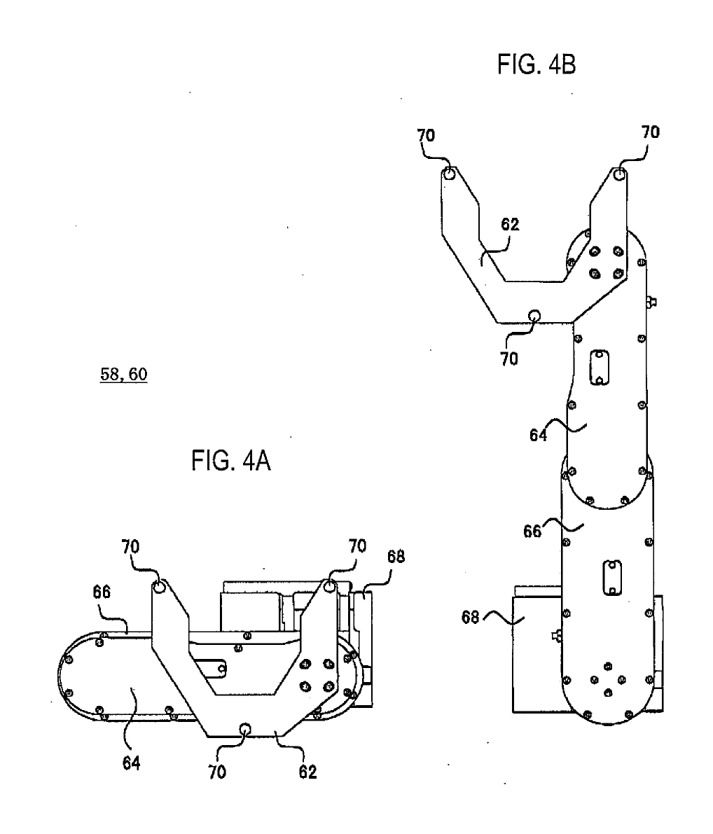

A first SCARA (Selective Compliant Assembly Robot Arm) arm 58 as a first boat conveying device and a second SCARA arm 60 as a second boat conveying device are provided in the inner rear area of the housing 12 in opposing relationship with the boat elevator 40. The first SCARA arm 58 and the second SCARA arm 60 will now be described with reference to FIGS. 3, 4A and 4B.

FIG. 3 is a perspective view showing the first SCARA arm 58 or the second SCARA arm 60 used in the present embodiment. FIGS. 4A and 4B are top views of the first SCARA arm 58 or the second SCARA arm 60 shown in FIG. 3. FIG. 4A depicts a standby state of the SCARA arms and FIG. 4B depicts a limited state of the SCARA arms.

Each of the first SCARA arm 58 and the second SCARA arm 60 includes a boat support portion 62 configured to support the boats 48 and 49 thereon, a first arm 64 configured to rotatably support the boat support portion 62, a second arm 66 configured to rotatably support the first arm 64 and a base portion 68 configured to support the second arm 66 in a rotatable, vertically movable and back-and-forth movable manner.

The boat support portion 62 is shown to have a rectangular shape but may be formed to have, e.g., a U-shape. Also, in case of supporting the boats 48 and 49, the surface of the boat support portion 62 facing the boats 48 and 49 may have a concave shape. At least three protrusions 70 are formed on the upper surface of the boat support portion 62. The three protrusions 70 are inserted into the holes (not shown) formed on the lower surface of each of the boats 48 and 49, whereby the boats 48 and 49 are reliably supported by the first SCARA arm 58 and the second SCARA arm 60.

In other words, the boat support portion 62 is rotatably supported at its end by the first arm 64 which in turn is rotatably supported at its end by the second arm 66 which in turn is rotatably supported at its end by the base portion 68. Thus, each of the first SCARA arm 58 and the second SCARA arm 60 waits in a folded state by the rotation of the respective components about their ends (i.e., in a standby state) and extends rectilinearly in a limited time (i.e., in a limited state).

A boat support table 46 configured to support the boats 48 and 49 is arranged in such a position that does not hinder the loading and unloading operation of the boat elevator 40 (a table retreat position D as shown in FIG. 2). The boat support table 46 is movable from the table retreat position D to the boat loading/unloading position A right below the reactor 52. While discharging a processed substrate or charging an unprocessed substrate, the boat support table 46 is moved to the boat loading/unloading position A.

Next, description will be made on the operations of the substrate processing apparatus 10 of the first embodiment.

The position right below the reactor 52 where the boats 48 and 49 are loaded into or unloaded from the reactor 52 is referred to as boat loading/unloading position A. The position near the substrate transfer machine 32 facing the installation surface of the boat elevator 40 is referred to as boat standby position B. The position interposing the table retreat position D between itself and the boat standby position B is referred to as boat retreat position C. The first SCARA arm 58 is arranged in the boat standby position B with the second SCARA arm 60 arranged in the boat retreat position C (see FIG. 2).

The substrate storage cassette 18 is brought onto the cassette delivery stage 16 by an external conveying device not shown in the drawings. Twenty five substrates 38 are charged into the substrate storage cassette 18 at a predetermined vertical pitch. The substrate storage cassette 18 is an air-tight sealed container which can prevent infiltration of particles. Thus, even when the substrate storage cassette 18 is positioned outside the housing 12, it can prevent contamination of particles.

The substrate storage cassette 18 is placed on the cassette opener 22 or conveyed to the cassette rack 24 by means of the cassette loader 20. The door of the substrate storage cassette 18 placed on the lifting table 28 is opened by the door opening/closing mechanism 30.

The substrate transfer machine 32 is movable up and down, movable back and forth and rotatable. The substrate transfer machine 32 is moved to a predetermined height by a transfer machine elevator. The tweezers 34 are moved forward to grip one of the substrates 38 existing within the substrate storage cassette 18. Then, the tweezers 34 are moved backwards to unload the substrate 38.

The tweezers 34 are rotated and height-adjusted. Thereafter, the tweezers 34 enter the boat 48 or 49 to load the substrate 38 into the boat 48 or 49 in a horizontal posture.

The first SCARA arm 58 and the second SCARA arm 60 are individually movable in transverse, vertical and back-and-forth directions. The boat support table 46 is independently movable from the table retreat position D to the boat loading/unloading position A in transverse and back-and-forth directions.

Next, description will be made on the operations of the first SCARA arm 58 and the second SCARA arm 60.

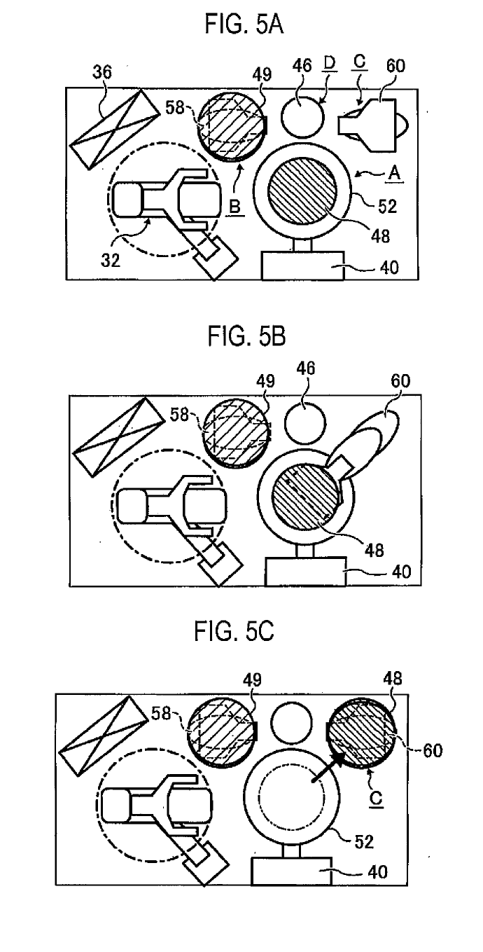

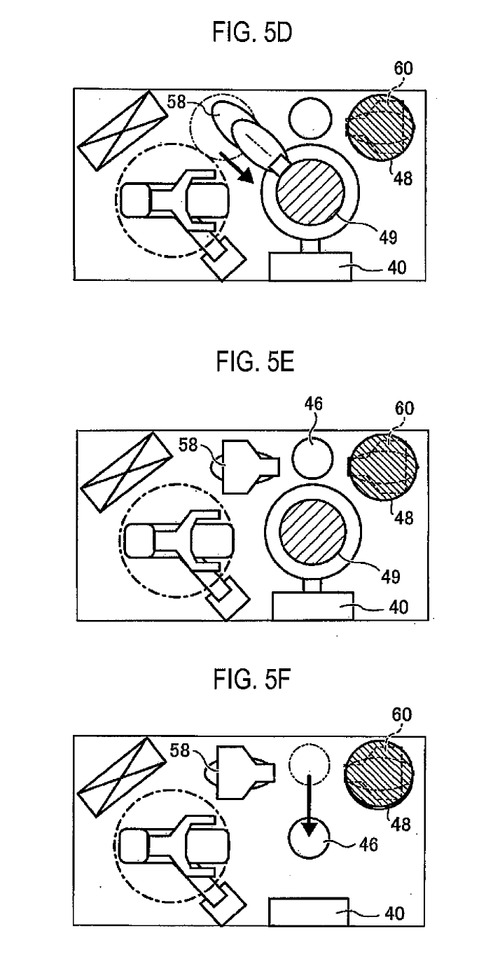

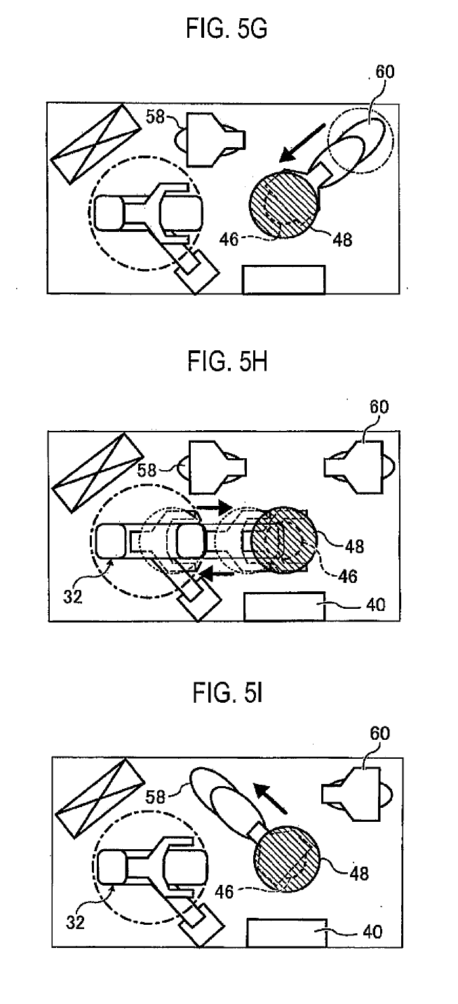

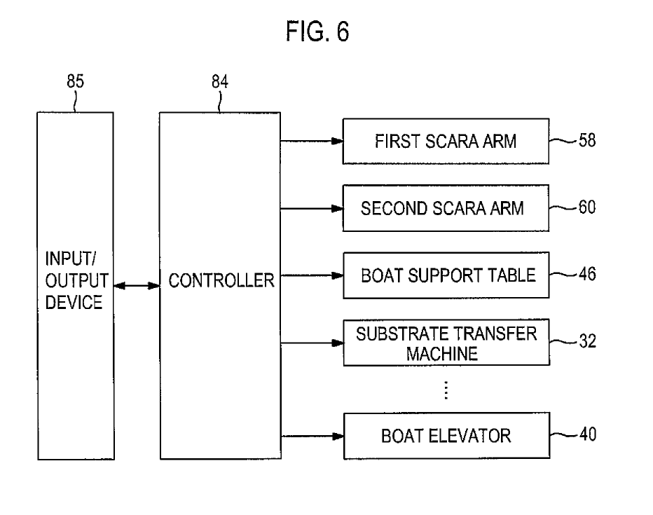

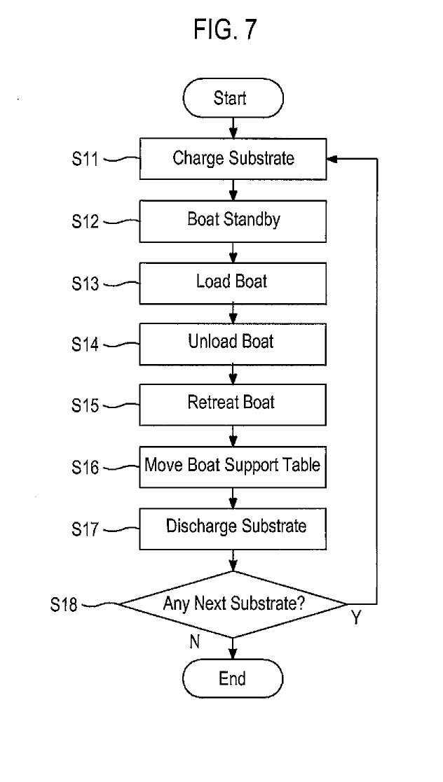

FIGS. 5A through 5I are top plan views of a conveying chamber of the substrate processing apparatus 10. FIG. 6 shows the configuration of a controller 84 as a control unit of the substrate processing apparatus 10. The controller 84 controls the first SCARA arm 58, the second SCARA arm 60, the boat support table 46, the substrate transfer machine 32 and the boat elevator 40 through an input/output device 85. FIG. 7 shows a control flow performed by the controller 84. In the following description, the operations of the respective parts in the substrate processing apparatus 10 of the present embodiment are controlled by the controller 84.

As shown in FIG. 5A, the first boat 48 holding a processed substrate 38 is unloaded from the reactor 52 using the boat elevator 40 (step S14). At this time, the second boat 49 holding an unprocessed substrate 38 is supported by the first SCARA arm 58 and waits in the boat standby position B (step S12).

As shown in FIGS. 5B and 5C, the unloaded first boat 48 is supported by the action of the second SCARA arm 60 in the boat loading/unloading position A and is moved back to the boat retreat position C. The processed substrate 38 held in the first boat 48 is cooled to a specified temperature (step S15).

Then, as shown in FIGS. 5D and 5E, while the processed substrate 38 held in the first boat 48 is being cooled in the boat retreat position C, the second boat 49 holding the unprocessed substrate 38 and waiting in the boat standby position B is supported by the action of the first SCARA arm 58 and conveyed to the boat loading/unloading position A.

As shown in FIG. 5F, the second boat 49 is loaded into the reactor 52 by the boat elevator 40 (step S13). The boat support table 46 arranged in the table retreat position D is moved to the boat loading/unloading position A (step S16).

As shown in FIG. 5G, if the processed substrate 38 held in the first boat 48 (which has been moved back to the boat retreat position C) is cooled to the specified temperature, the first boat 48 is supported by the action of the second SCARA arm 60 and conveyed onto the boat support table 46 arranged in the boat loading/unloading position A.

Thereafter, as shown in FIG. 5H, the processed substrate 38 held in the first boat 48 by the action of the substrate transfer machine 32 is discharged from the substrate storage cassette 18 placed on the cassette opener 22 (step S17). If the processed substrate 38 is charged into the substrate storage cassette 18, the cassette 18 is conveyed to the cassette delivery stage 16 by the cassette loader 20 and then taken out by an external conveying device. The substrate storage cassette 18 charged with unprocessed substrates 38 is transferred to the cassette opener 22 by the cassette loader 20. The substrate transfer machine 32 transfers one of the unprocessed substrates 38 from the substrate storage cassette 18 to the empty first boat 48 arranged in the boat loading/unloading position A (step S).

As shown in FIG. 5I, the first boat 48 holding the unprocessed substrate 38 is supported by the action of the first SCARA arm 58 and waits in the boat standby position B (step S12).

The batch processing of the substrates is performed by repeating the steps illustrated in FIGS. 5A through 5I.

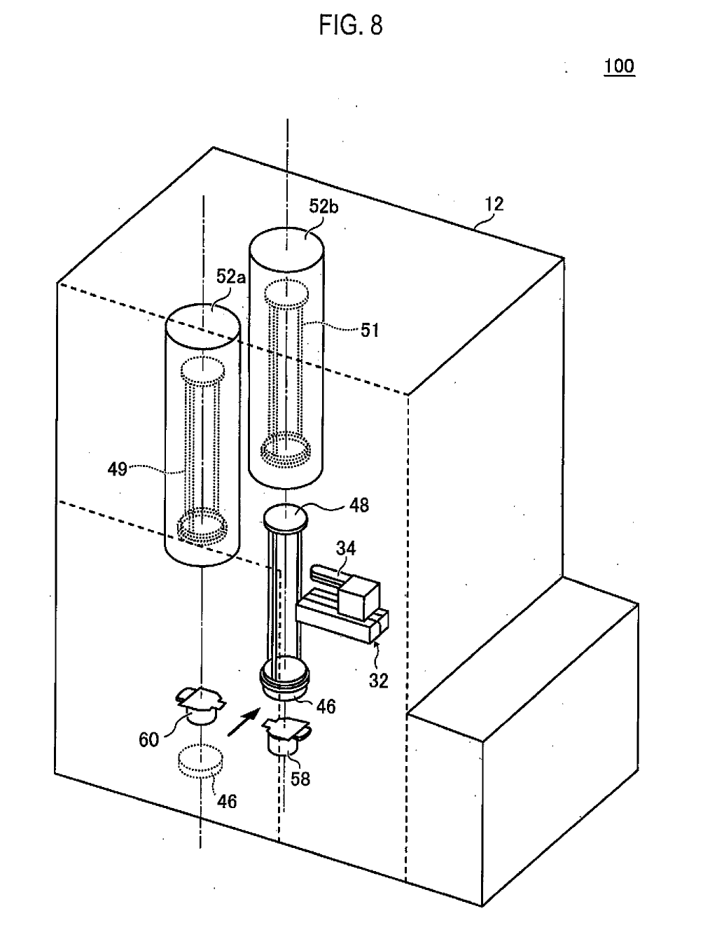

Next, description will be made on a two-reactor three-boat-interchangeable substrate processing apparatus according to a second embodiment. FIG. 8 is a schematic perspective view showing the substrate processing apparatus 100 of the second embodiment. Descriptions of the same elements or functions as the first embodiment will be omitted, and only different elements or functions of the substrate processing apparatus 100 of the second embodiment from the substrate processing apparatus 10 of the first embodiment will be described.

In the substrate processing apparatus 100 of the second embodiment, two boat elevators 40 (not shown in FIG. 8) are provided at the rear surface side of the substrate transfer machine 32. Each of the boat elevators 40 includes a lifting arm 42 (not shown in FIG. 8). The lifting arms 42 of the boat elevators 40 may be moved up and down by lifting motors (not shown in the drawings).

Reactor mouth caps 44a and 44b (not shown in FIG. 8) are provided in the tip end portions of the lifting arms 42. Substrate holders (boats) 48, 49 and 51 configured to horizontally hold processing-target substrates (e.g., wafers) 38 in multiple layers are placed on the upper surfaces of the reactor mouth caps 44a and 44b.

In the substrate processing apparatus 100 of the second embodiment, two reactors, i.e., first and second reactors 52a and 52b each including a reaction chamber and a heater are provided above the reactor mouth caps 44a and 44b, respectively.

Each of the first and second reactors 52a and 52b has a reactor mouth (not shown) defined in the lower portion thereof. The position right below the reactor mouth of the first reactor 52a becomes a boat loading/unloading position A and also a substrate loading/unloading position where the substrates 38 are loaded into or unloaded from the boats 48, 49 and 51. In other words, the first boat 48, the second boat 49 and the third boat 51 are alternately loaded into and unloaded from the reactor mouths of the first and second reactors 52a and 52b. The reactor mouth caps 44a and 44b are fitted to the reactor mouths of the first and second reactors 52a and 52b to seal the first and second reactors 52a and 52b to be air-tight. The substrates 38 are processed by the first and second reactors 52a and 52b under the presence of a reaction gas.

A first SCARA arm 58 as a first boat conveying device and a second SCARA arm 60 as a second boat conveying device are provided below the first and second reactors 52a and 52b to face each other.

A boat support table 46 configured to support the boats 48, 49 and 50 is provided below the first and second reactors 52a and 52b. The boat support table 46 is movable from the position right below the first reactor 52a to the position right below the second reactor 52b.

The boat support table 46 is moved from a first boat loading/unloading position A right below the first reactor 52a to a second boat loading/unloading position B right below the second reactor 52b either when discharging a processed substrate or charging an unprocessed substrate (e.g., to the substrate storage cassette 18), when unloading the boat carrying a processed substrate from one of the first and second reactors 52a and 52b, or when loading the boat carrying an unprocessed substrate into one of the first and second reactors 52a and 52b.

Description will now be made on the operations of the first SCARA arm 58 and the second SCARA arm 60 in the substrate processing apparatus 100 of the second embodiment.

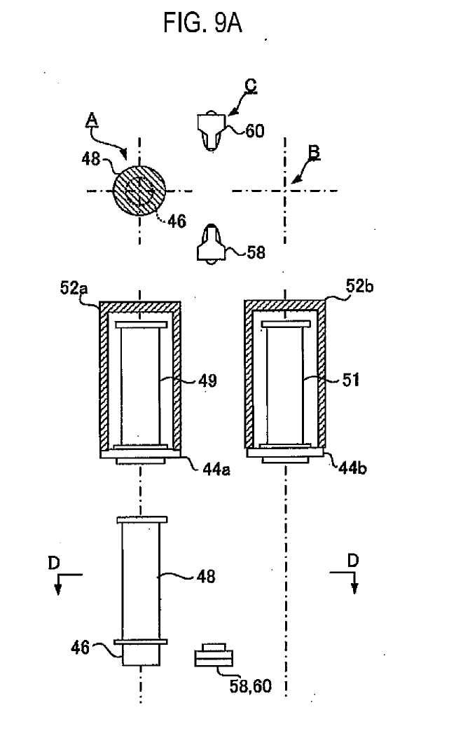

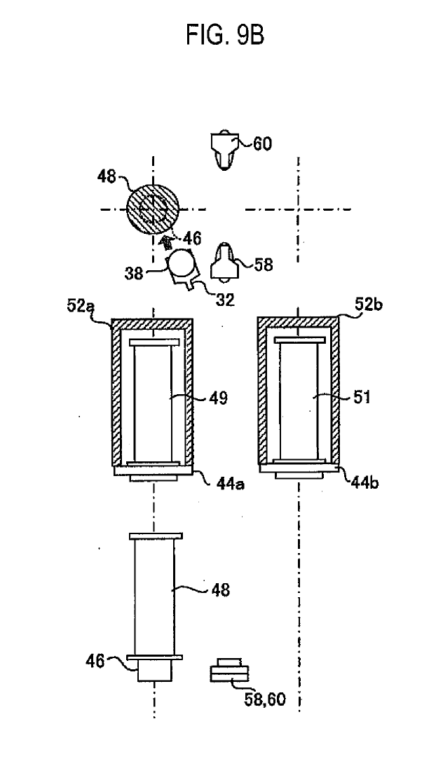

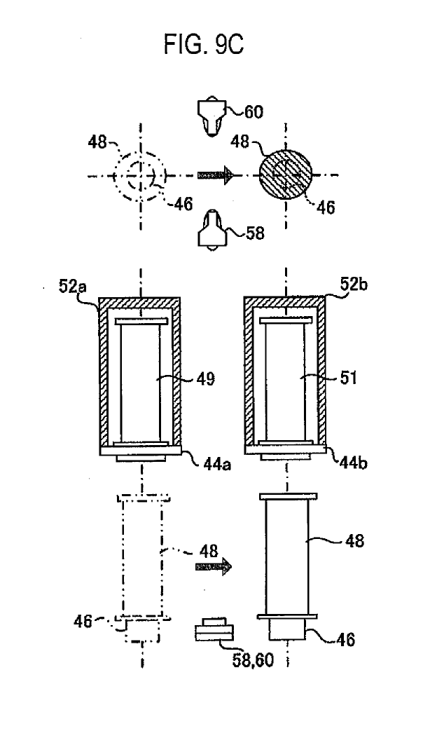

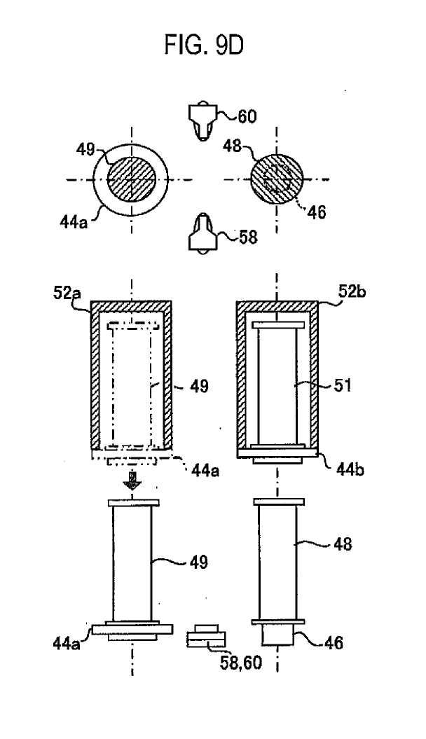

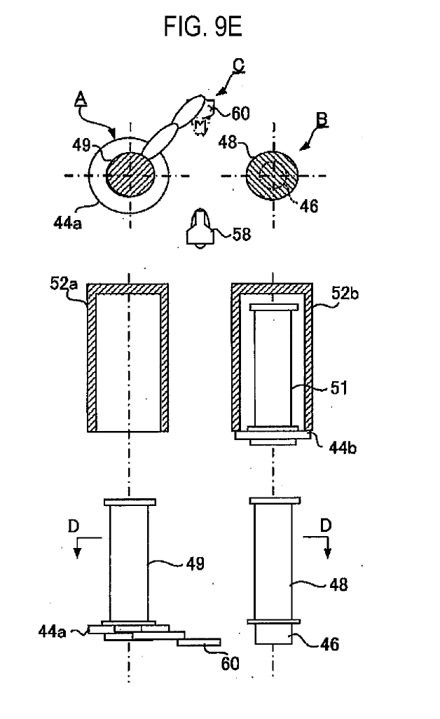

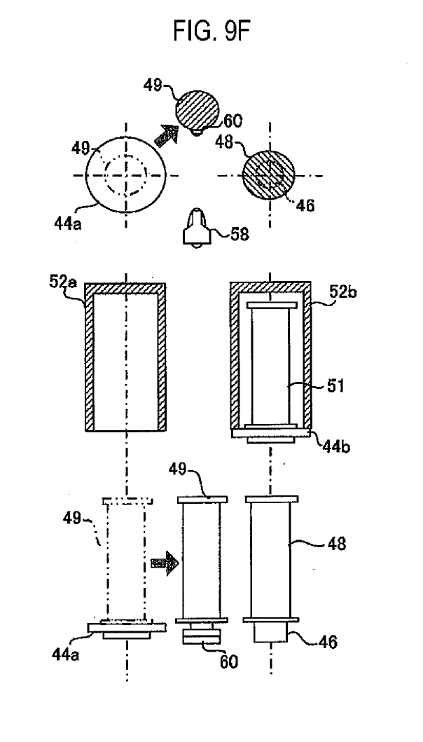

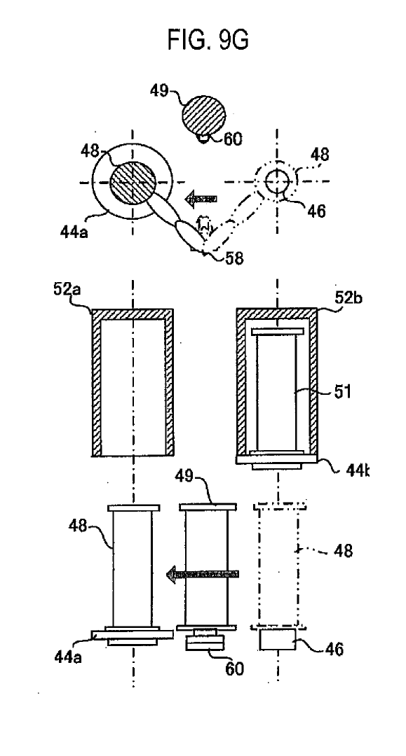

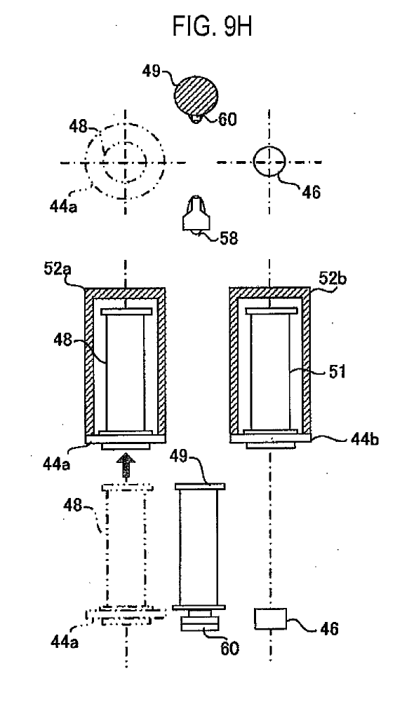

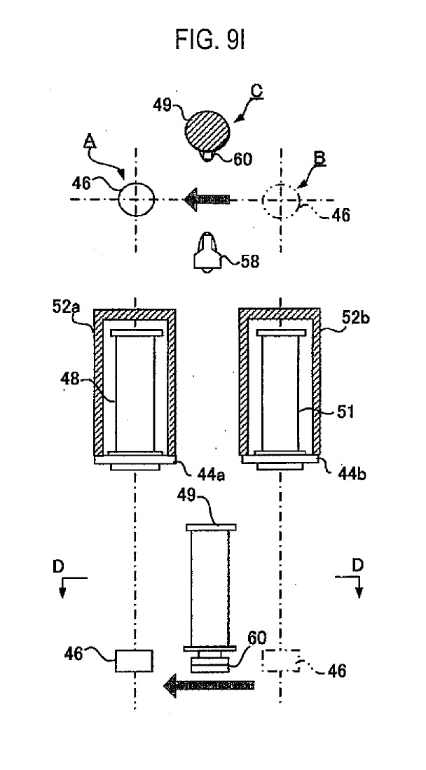

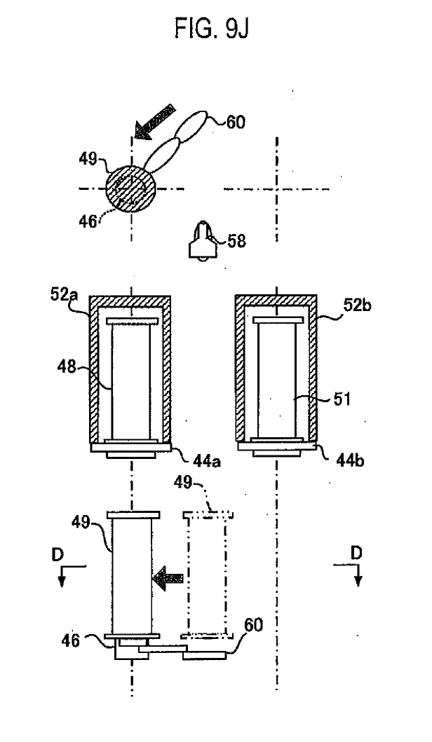

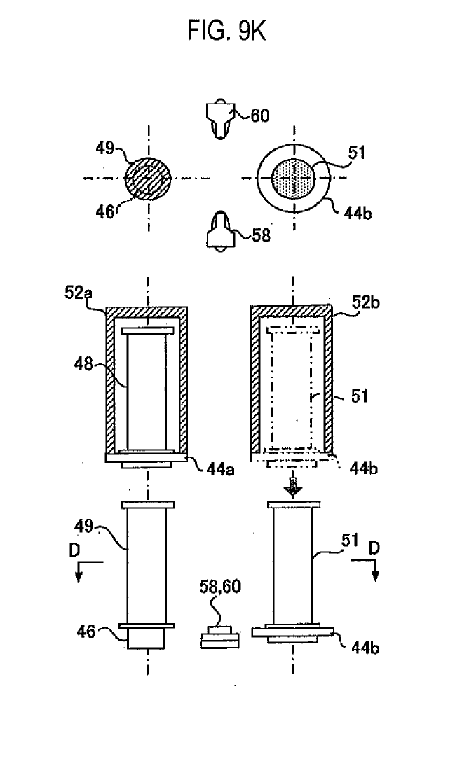

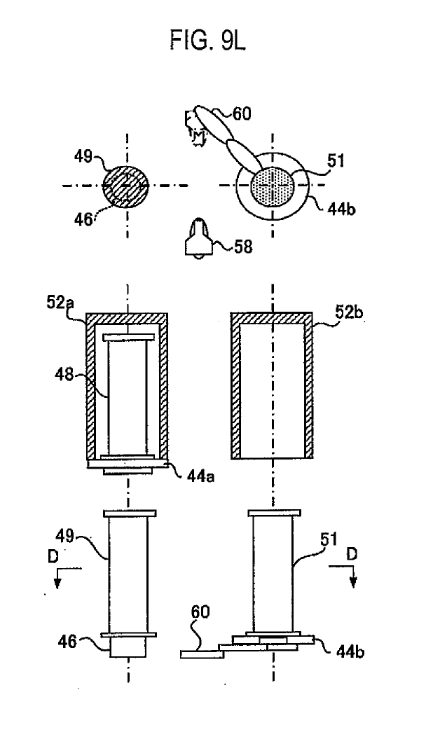

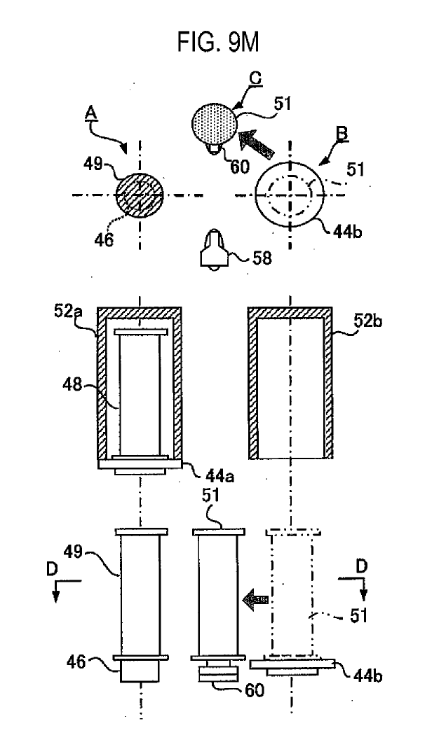

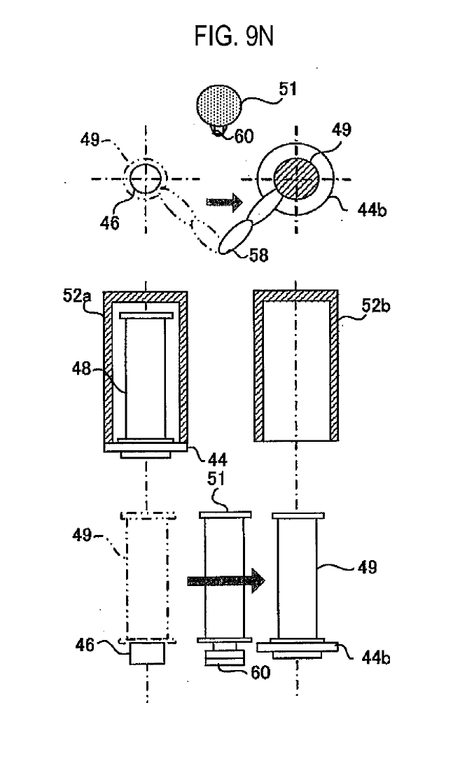

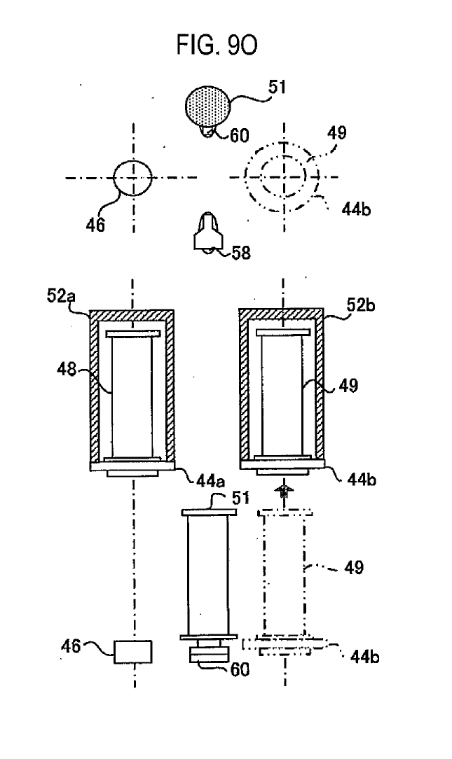

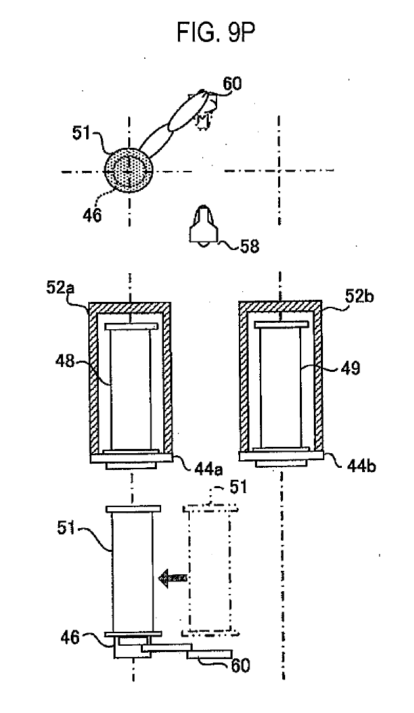

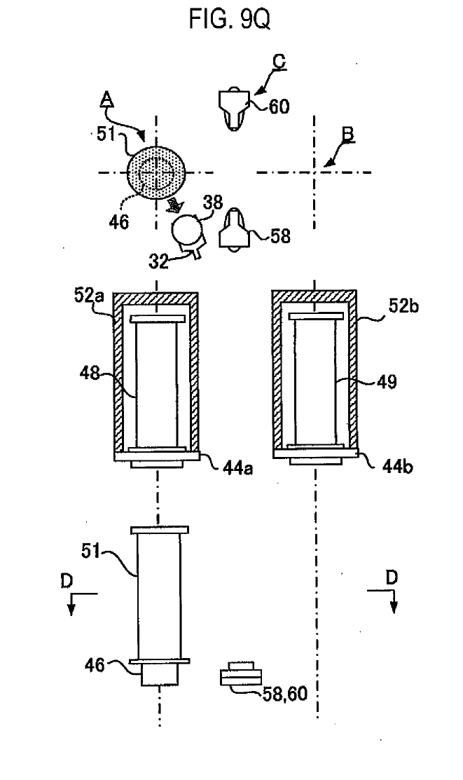

FIGS. 9A through 9Q are diagrams for explaining the operation of the substrate processing apparatus 100 of the second embodiment. The lower part in each diagram is a side elevational view of the reactors 52a and 52b and the SCARA arms 58 and 60, and the upper part in each diagram is a cross sectional view taken along line D-D in the lower part. In this configuration, the substrate processing apparatus 100 is controlled by a controller 84. The controller 84 controls the first SCARA arm 58, the second SCARA arm 60, the boat support table 46, the substrate transfer machine 32 and the heaters (not shown) of the reactors 52a and 52b through an input/output device 85. In the following description, the operations of the respective parts of the substrate processing apparatus 100 of the second embodiment are controlled by the controller 84.

The position right below the first reactor 52a where the boats 48, 49 and 51 are loaded into or unloaded from the first reactor 52a is referred to as first boat loading/unloading position A. The position right below the second reactor 52b is referred to as a second boat loading/unloading position B (or boat standby position B). The retreat position of the second SCARA arm 60 provided opposite the first SCARA arm 58 located near the substrate transfer machine 32 is referred to as boat retreat position C.

A shown in FIGS. 9A and 9B, by the action of the substrate transfer machine 32, an unprocessed substrate 38 is transferred (charged) to the empty first boat 48 arranged in the first boat loading/unloading position A (the first boat, step S11). At this time, the empty first boat 48 is placed on the boat support table 46 located in the first boat loading/unloading position A. The unprocessed substrate 38 held in the second boat 49 is thermally treated within the first reactor 52a, and the unprocessed substrate 38 held in the third boat 51 is thermally treated within the second reactor 52b.

Then, as shown in FIG. 9C, by the action of the boat support table 46, the first boat 48 holding the unprocessed substrate 38 is moved to the second boat loading/unloading position B, i.e., the boat standby position B (the first boat, step S12).

As shown in FIG. 9D, the second boat 49 holding the processed substrate 38 is unloaded from within the first reactor 52a to the first boat loading/unloading position A by the boat elevator 40 (the second boat, step S14). At this time, the first boat 48 holding the unprocessed substrate 38 waits in the second boat loading/unloading position B, i.e., the boat standby position B.

Thereafter, as shown in FIGS. 9E and 9F, the second boat 49 holding the processed substrate 38 is supported by the action of the second SCARA arm 60 and moved back to the boat retreat position C. The processed substrate 38 held in the second boat 49 is cooled to a specified temperature (the second boat, step S15).

Referring to FIG. 9G, while the processed substrate 38 held in the second boat 49 is being cooled in the boat retreat position C, the first boat 48 holding the unprocessed substrate 38 and waiting in the second boat loading/unloading position B (the boat standby position B) is supported by the action of the first SCARA arm 58 and conveyed to the first boat loading/unloading position A.

As illustrated in FIG. 9H, the first boat 48 holding the unprocessed substrate 38 is loaded from the first boat loading/unloading position A into the first reactor 52a by the boat elevator 40 (the first boat, step S13).

As shown in FIGS. 9I and 9J, the boat support table 46 is moved from the second boat loading/unloading position B (the boat standby position B) to the first boat loading/unloading position A. At this time, the unprocessed substrate 38 held in the first boat 48 is thermally treated within the first reactor 52a. The second boat 49 moved back to the boat retreat position C is supported by the action of the second SCARA arm 60 and conveyed onto the boat support table 46 located in the first boat loading/unloading position A (the second boat, step S16).

As shown in FIG. 9K, the third boat 51 holding the processed substrate 38 is unloaded from within the second reactor 52b to the second boat loading/unloading position B by the boat elevator 40 (the third boat, step S14).

As shown in FIGS. 9L and 9M, the third boat 51 holding the processed substrate 38 is supported by the action of the second SCARA arm 60, moved back to the boat retreat position C and cooled (the third boat, step S15).

Then, as shown in FIG. 9N, the second boat 49 holding the processed substrate 38 is supported by the action of the first SCARA arm 58 and conveyed from the first boat loading/unloading position A to the second boat loading/unloading position B, i.e., the boat standby position B (the second boat, step S12).

FIG. 9O illustrates that the second boat 49 holding the processed substrate 38 is conveyed from the second boat loading/unloading position B into the second reactor 52b by the boat elevator 40 and then thermally treated (the second boat, step S13).

As shown in FIG. 9P, the third boat 51, which has been moved back to the boat retreat position C, is supported by the action of the second SCARA arm 60 and conveyed onto the boat support table 46 arranged in the first boat loading/unloading position A.

As shown in FIG. 9Q, by the action of the substrate transfer machine 32, the processed substrate 38 held in the third boat 51 is returned (discharged) to the substrate storage cassette 18 (not shown in FIG. 8) placed on the cassette opener 22 (not shown in FIG. 8) (the third boat, step S17).

The batch processing of the substrates is performed by repeating the steps illustrated in FIGS. 9A through 9Q.

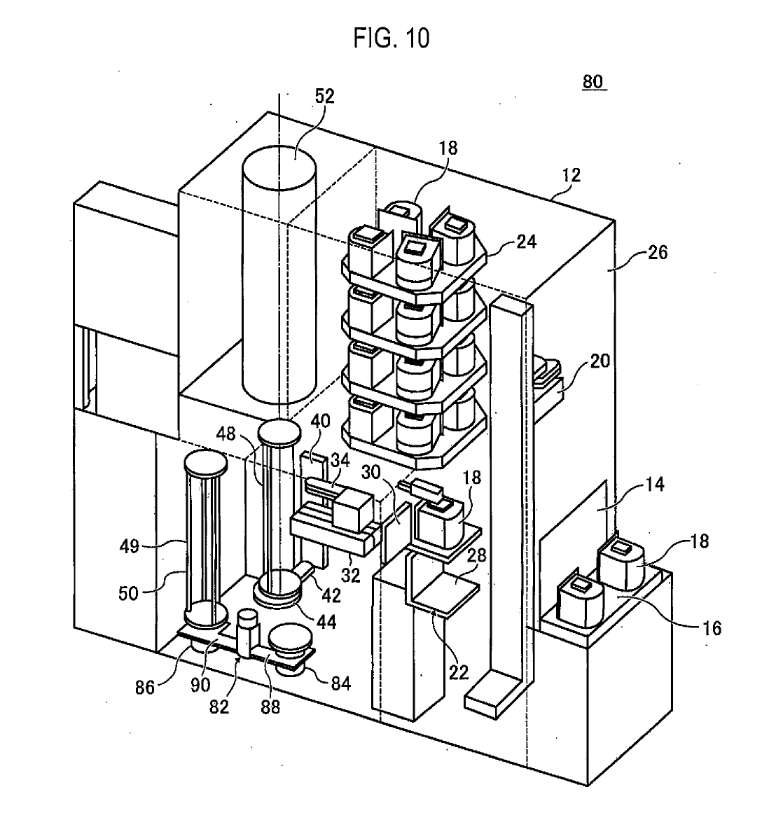

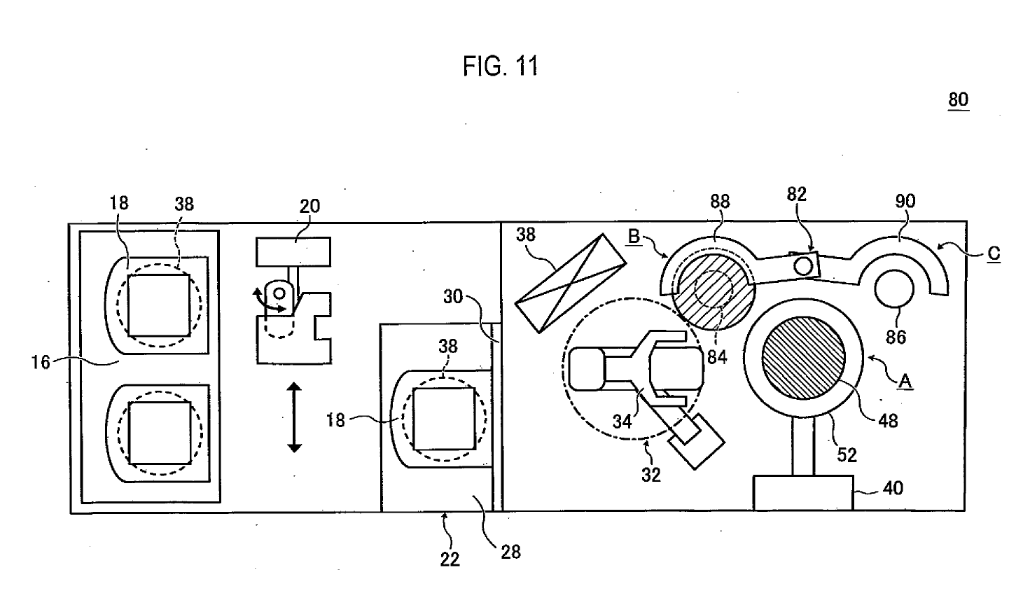

Next, description will be made on a substrate processing apparatus 80 according to a comparative example of the substrate processing apparatus 10 of the present embodiment. FIG. 10 is a schematic perspective view of a substrate processing apparatus 80 according to a comparative example. FIG. 11 is a top plan view of the substrate processing apparatus 80 shown in FIG. 10. In the following description, same elements or functions as the above embodiments will be omitted, and only elements or functions differing from the substrate processing apparatus 10 of the first embodiment will be described.

The substrate processing apparatus 80 of the comparative example includes one boat conveying device 82 for conveying wafers and two first and second boat support tables 84 and 86 for supporting boats. The boat conveying device 82 includes two arms 88 and 90 semicircular in shape. The first boat support table 84 is provided in the boat standby position B described earlier, and the second boat support table 86 is provided in the boat retreat position C. In other words, the two arms 88 and 90 of the boat conveying device 82 are rotated and vertically moved to convey two boats 48 and 49 between the boat loading/unloading position A, the boat standby position B and the boat retreat position C.

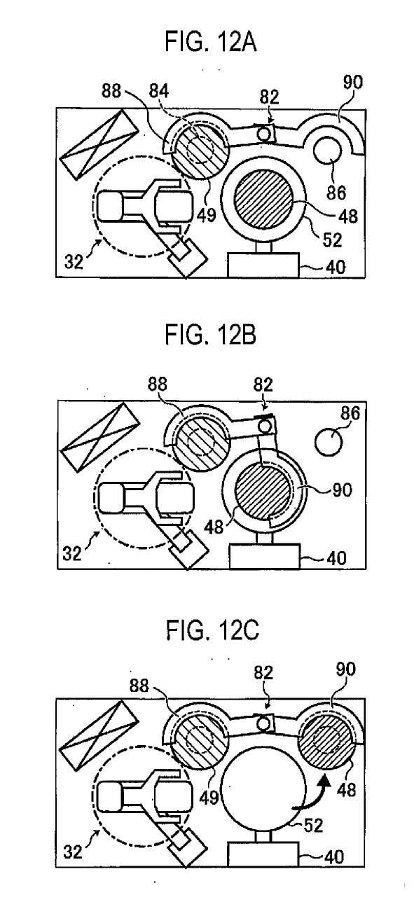

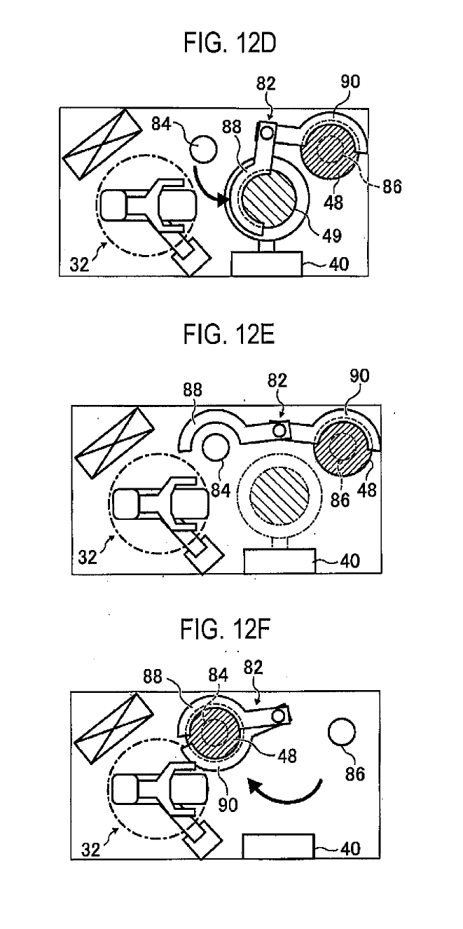

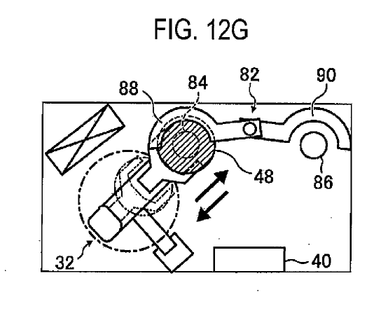

FIGS. 12A through 12G are top plan views of a conveying chamber of the substrate processing apparatus 80 of the comparative example. In the following description, the operations of the respective parts of the substrate processing apparatus 80 of the comparative example are controlled by a controller 84.

As shown in FIG. 12A, the first boat 48 holding a processed substrate is unloaded from the reactor 52 by the boat elevator 40. At this time, the second boat 49 holding an unprocessed substrate 38 is placed on the first boat support table 84.

Then, as shown in FIGS. 12B and 12C, the unloaded first boat 48 is conveyed onto the second boat support table 86 by the second arm 90 of the boat conveying device 82 and is cooled.

Referring to FIGS. 12D and 12E, while the processed substrate 38 is cooled, the second boat 49 waiting above the first boat support table 84 is conveyed to the boat loading/unloading position A by the first arm 88 of the boat conveying device 82 and loaded into the reactor 52 by the boat elevator 40.

As shown in FIG. 12F, the processed substrate 38 is subjected to cooling, and the first boat 48 placed on the second boat support table 86 is conveyed onto the first boat support table 84 by the second arm 90 of the boat conveying device 82.

Then, as shown in FIG. 12G, the processed substrate is discharged from the first boat 48 placed on the first boat support table 84 (e.g., to the substrate storage cassette 18) by means of the substrate transfer machine 32, and the unprocessed substrate is charged to the first boat 48 (e.g., from the substrate storage cassette 18).

In the two-boat-type substrate processing apparatus 80 of the comparative example described above with reference to FIGS. 10 through 12G, when operating two boats, the substrate 38 is charged and discharged in the position of the boat support table 84, which is located apart from the position right below the reactor 52. Further, when operating one boat, the substrate 38 is charged and discharged in the boat positioned right below the reactor 52. This makes it necessary to coordinate the operations of charging and discharging the substrates at two different locations (e.g., the position of the boat support table 84 and the position right below the reactor 52). With the two-boat-type substrate processing apparatus 10 of the first embodiment, however, the charging and discharging operations of the substrates can be coordinated only in the position of the boat support table 86 right below the reactor 52 either when operating two boats or when operating one boat. This facilitates coordinating the charging and discharging operations of the substrates. Similarly, with the three-boat-type substrate processing apparatus 100 of the second embodiment, the charging and discharging operations of the substrates can be coordinated only in the position of the boat support table 86 right below the reactor 52a. This also facilitates coordinating the charging and discharging operations of the substrates.

As compared with the substrate processing apparatus 80 of the comparative example, the substrate processing apparatus 10 or 100 of the first and second embodiments can be arranged in a footprint-reducing manner. In other words, it is possible to provide a two-boat-type or three-boat-type substrate processing apparatus capable of reducing the space while increasing the throughput even when applied to a vertical substrate processing apparatus for processing wafers of large diameter, e.g., 450 mm. While the use of 450 mm-diameter wafers has been described above by way of example, the diameter of the substrate is not limited thereto but may be further increased. With the first and second embodiments, the two boat conveying devices can simultaneously perform their respective operations within the conveying chamber, which is effective in increasing the throughput. While the use of the two boat conveying devices within the conveying chamber has been described above by way of example, the number of boat conveying devices is not limited thereto but may be three or more. While the boat support table 46 has been described to move (e.g., at a predetermined speed) to the position right below the reactor 52 by way of example, the above embodiments are not limited thereto but may be applied to a case where the boat support table 46 is ejected to quickly reach the position right below the reactor 52. Since the substrate processing apparatus of the above embodiments may make use of the configuration of the existing substrate processing apparatus, the above embodiments may be implemented without significant modifications in configuration.

Accordingly, the above embodiments make it possible to increase the throughput while keeping the footprint layout reduced.

The above embodiments may be employed in semiconductor manufacturing technology and, more particularly, heat treatment technology with which processing-target substrates are put into a processing chamber and processed in a heated state. For example, the above embodiments may be effectively applied to a substrate processing apparatus in which semiconductor wafers for production of semiconductor integrated circuit devices (semiconductor devices) are subjected to oxidation, diffusion or ion implantation and then subjected to reflow, annealing and thermal-CVD film formation for carrier activation and planarization.

While certain embodiments have been described above, these embodiments have been presented by way of example only, and are not intended to limit the scope of the inventions. Indeed, the novel substrate processing apparatus and method described herein may be embodied in a variety of other forms; furthermore, various omissions, substitutions and changes in the form of the substrate processing apparatus and method described herein may be made without departing from the sprit of the inventions. The accompanying claims and their equivalents are intended to cover such forms or modifications as would fall within the scope and sprit of the inventions.

What is claimed is:

1. A substrate processing apparatus, comprising:
a reactor;
at least two boat conveying devices configured to convey at least two boats;
at least one boat support table configured to support the at least two boats, the boat support table being movable to a position below the reactor; and
a control unit configured to control the boat conveying devices such that when a first boat of the at least two boats supported by a first boat conveying device of the plurality of boat conveying devices holds a processed substrate processed by the reactor and is moved back to a position spaced apart from the reactor, a second boat of the at least two boats holding an unprocessed substrate is loaded into the reactor using a second boat conveying device of the at least two boat conveying devices.

2. The apparatus of claim 1, wherein the control unit controls the movement of the boat support table to the position below the reactor, and controls the boat conveying devices to convey the first boat to the boat support table using the first boat conveying device, to discharge the processed substrate held in the first boat, to charge the unprocessed substrate to be subsequently processed into the first boat and to cause the first boat to wait in the position spaced apart from the reactor using the second boat conveying device.

3. A substrate processing apparatus, comprising:
at least two reactors;
at least two boat conveying devices configured to convey at least two boats;
at least one boat support table configured to support the at least two boats, the at least one boat support table being movable from a position below a first reactor of the at least two reactors to a position below a second reactor of the at least two reactors; and
a control unit configured to control the boat conveying devices such that, when a first boat of the at least two boats supported by a first boat conveying device of the at least two boat conveying devices holds a processed substrate processed by the first reactor and the first boat conveying device is moved back to a position spaced apart from the reactors, a second boat of the at least two boats holding an unprocessed substrate is moved into the first reactor using a second boat conveying device of the at least two boat conveying devices, the at least one boat support table is moved from the position below the first reactor to the position below the second reactor, the first boat is conveyed to the at least one boat support table using the first boat conveying device, the processed substrate held in the first boat is discharged, the unprocessed substrate to be subsequently processed is charged and moved to the first boat, and the first boat is caused to wait in the position spaced apart from the reactors.

4. A substrate processing method in a substrate processing apparatus comprising a first reactor and a second reactor, the method comprising:
holding a processed substrate processed by a first reactor in a first boat;
supporting the first boat with a first boat conveying device;
moving the first boat conveying device to a position spaced apart from the first and second reactors;
moving a second boat into the first reactor using a second boat conveying device, the second boat holding an unprocessed substrate.

5. The method of claim 4, further comprising:
moving a boat support table from the position below the first reactor to the position below the second reactor; and
conveying the first boat to the boat support table using the first boat conveying device.

6. The method of claim 5, further comprising:
discharging the processed substrate held in the first boat;
charging a unprocessed substrate to be subsequently processed into the first boat;
moving the first boat to the position spaced apart from the first and second reactors using the second boat conveying device.
